(19) United States
(12) Patent Application Publication
(10) Pub. No.: US 2026/0322029 A1
(43) Pub. Date: Oct. 15, 2026

(54) CONNECTOR DEVICE

(71) Applicant: Molex, LLC, Lisle, IL (US)

(72) Inventor: Che-Yuan Yang, New Taipei City (TW)

(21) Appl. No.: 19/450,799

(22) Filed: Jan. 16, 2026

(30) Foreign Application Priority Data
Jan. 24, 2025 (CN) 202510119122.0

(51) Int. Cl. H01R 13/533; H01R 12/72

(52) U.S. Cl. CPC H01R 13/533; H01R 12/722

(57) ABSTRACT

A connector device is provided to a board and allows a pluggable assembly to mate therewith. The connector device includes a receptacle assembly and a heat dissipating assembly. The receptacle assembly includes a plurality of cages and a plurality of connectors. The heat dissipating assembly includes a cold plate, the cold plate includes a body portion which is provided to the board, and a plurality of cantilever portions which are integrally formed with the body portion, bottoms of the plurality of cantilever portions respectively extend into top openings of the plurality of cages. One type of the cold plate further includes a cold pipe which is provided in the plurality of cantilever portions, the cold pipe contacts a top surface of the pluggable assembly which inserts into the receptacle assembly. The body portion of another type of the cold plate therein form a plurality of passageways which allow a cooling liquid to flow therethrough, the plurality of cantilever portions are solid heat dissipating plates, the bottom of the cantilever portion contacts a top surface of the pluggable assembly which inserts into the receptacle assembly. The structure design of the heat dissipating assembly indeed may have an effect that thermal conductivity is better and leakage of the cooling liquid is prevented

### TECHNICAL FIELD

The present disclosure relates to a connector device, and particularly relates to a connector device having a cantilever portion which performs heat exchange with a pluggable assembly.

### BACKGROUND

Chinese patent document CN118226592A discloses an optical module heat dissipating device. The optical module heat dissipating device includes an optical module cold plate and a plurality of optical cages. The optical module cold plate includes a liquid distributing portion, and a plurality of cold plate portions which are suspended and extend outwardly from a side of the liquid distributing portion and are correspondingly positioned above the plurality of optical cages respectively. The liquid distributing portion is provided with a liquid entering port and a liquid exiting port which are spaced apart from each other, a liquid entering passageway which is communicated with the liquid entering port, and a liquid returning passageway which is communicated with the liquid exiting port. Each cold plate portion is provided with a cooling passageway. The cooling passageway is provided with a liquid entering opening which is communicated with the liquid entering passageway, and a liquid exiting opening which is communicated with the liquid returning passageway. Each optical cage is used to allow an optical module to cooperatively mate therewith, may allow the optical module to push and contact the corresponding cool plate portion to perform heat exchange and be cooled down.

Further, the optical module cool plate is a cantilevered plate design. When each optical module mates with each cool plate portion, each cool plate portion will be pushed by the optical module to relatively warp upwardly, and at the same time has a restoring force which downwardly presses against the optical module. However, because the optical module cool plate is formed by two sheets which are connected up and down, and the cooling passageways are directly formed in the two sheets, after the plurality of cool plate portions swing up and down, the plurality of cool plate portions are prone to be deformed to generate crack, which results in occurring of leakage phenomena of the cooling liquid in the plurality of cooling passageways, in turn heat dissipating function fails. Thus the design of the optical module cool plate still needs to be improved.

### SUMMARY

Therefore, an object of the present disclosure is to provide a connector device which at least can overcome the deficiency of the prior art.

Accordingly, a connector device of the present disclosure is provided to a board and allows a pluggable assembly to mate therewith, the connector device comprises a receptacle assembly and a heat dissipating assembly. The receptacle assembly comprises a plurality of cages and a plurality of connectors respectively provided in the plurality of cages, each cage is provided with a top opening. The heat dissipating assembly comprises a cold plate, the cold plate comprises a body portion which is provided to the board, a plurality of cantilever portions which protrude from the body portion and are spaced apart from the board, and a cold pipe which extends in the plurality of cantilever portions, the body portion and the plurality of cantilever portions are integrally formed, the receptacle assembly is positioned between the board and the plurality of cantilever portions, bottoms of the plurality of cantilever portions respectively extend into the top openings of the plurality of cages, when the pluggable assembly inserts into the receptacle assembly, the cold pipe contacts a top surface of the pluggable assembly.

In an implementing manner, each cantilever portion forms a U-shaped groove, the cold pipe is secured to the U-shaped groove, and the cold pipe extends out of the bottom of the cantilever portion, or is flush with the bottom of the cantilever portion.

In an implementing manner, each cage has a bottom plate, two side plates which respectively extend upwardly from a left side and a right side of the bottom plate, and a rear plate which extends upwardly from a rear side of the bottom plate, a height of a top edge of each side plate is equal to a height of the top opening and is higher than a height of a top edge of the rear plate, the rear plate is used to support the corresponding cantilever portion.

In an implementing manner, the cold pipe comprises an inlet end, an outlet end and a main pipe portion which connects the inlet end and the outlet end, the main pipe portion extends in the plurality of cantilever portions.

In an implementing manner, the cold pipe is a copper pipe.

In an implementing manner, the main pipe portion comprises a plurality of curved pipe segments which are respectively provided in the plurality of cantilever portions, and a plurality of connecting pipe segments which are provided in the body portion and each connect the two adjacent curved pipe segments, each curved pipe segment is in form of U-shape and an opening of the U-shape is toward the body portion, each connecting pipe segment is in form of reversed U-shape and an opening of the reversed U-shape is toward the plurality of cantilever portions.

In an implementing manner, the connector device further comprises an elastic pressing assembly, the elastic pressing assembly comprises a fixing plate which is positioned above and spaced apart from the plurality of cantilever portions, and a plurality of elastic members which are provided between the plurality of cantilever portions and the fixing plate, the plurality of elastic members respectively apply elastic forces toward the plurality of cantilever portions.

A technical effect of the present disclosure lies in that: a design that the cold pipe is wrapped in the cantilever portions may have a technical effect that thermal conductivity is better and leakage of the cooling liquid is prevented.

Therefore, an object of the present disclosure is to provide a connector device which at least can overcome the deficiency of the prior art.

Accordingly, a connector device of the present disclosure is provided to a board and allows a pluggable assembly to mate therewith, the connector device comprises a receptacle assembly and a heat dissipating assembly. The receptacle assembly comprises a plurality of cages and a plurality of connectors respectively provided in the plurality of cages, each cage is provided with a top opening. The heat dissipating assembly comprises a cold plate, the cold plate comprises a body portion which is provided to the board, and a plurality of cantilever portions which protrude from the body portion and are spaced apart from the board, the receptacle assembly is positioned between the board and the plurality of cantilever portions, bottoms of the plurality of cantilever portions respectively extend into the top openings of the plurality of cages, the body portion comprises a hollow cavity and a plurality of heat dissipating fins which are arranged in the hollow cavity, the plurality of heat dissipating fins and the hollow cavity form a plurality of passageways which allow a cooling liquid to flow therethrough, the plurality of cantilever portions are solid heat dissipating plates, and are thermally engaged with the body portion respectively, when the pluggable assembly inserts into the receptacle assembly, the bottom of the cantilever portion contacts a top surface of the pluggable assembly.

In an implementing manner, each cage has a bottom plate, two side plates which respectively extend upwardly from a left side and a right side of the bottom plate, and a rear plate which extends upwardly from a rear side of the bottom plate, a height of a top edge of each side plate is equal to a height of the top opening and is higher than a height of a top edge of the rear plate, the rear plate is used to support the corresponding cantilever portion.

In an implementing manner, the connector device further comprises an elastic pressing assembly, the elastic pressing assembly comprises a fixing plate which is positioned above and spaced apart from the plurality of cantilever portions, and a plurality of elastic members which are provided between the plurality of cantilever portions and the fixing plate, the plurality of elastic members respectively apply elastic forces toward the plurality of cantilever portions.

A technical effect of the present disclosure lies in that: that the cantilever portions of the cold plate employ solid heat dissipating plates may promote heat dissipating effect, moreover, the cooling liquid only flows in the passageways of the body portion, does not flow to the plurality of cantilever portions which are connected with the body portion, a technical effect that leakage of the cooling liquid does not occur due to flex deformation of the plurality of cantilever portions is achieved.

### BRIEF DESCRIPTION OF THE DRAWINGS

Other features and effects of the present disclosure will be apparent from embodiments with reference to the drawings, in which:

FIG. 1 is a perspective view illustrating a first embodiment of a connector device of the present disclosure;

FIG. 2 is an exploded perspective view illustrating the first embodiment;

FIG. 3 is a top view illustrating the first embodiment;

FIG. 4 is a cross-sectional side view illustrating the first embodiment;

FIG. 5 is a cross-sectional front view illustrating the first embodiment;

FIG. 6 is a cross-sectional front view illustrating another implementing manner of the first embodiment;

FIG. 7 is a perspective view illustrating a second embodiment of the connector device of the present disclosure;

FIG. 8 is an exploded perspective view illustrating the second embodiment;

FIG. 9 is an exploded rear perspective view illustrating the second embodiment;

FIG. 10 is a top view illustrating the second embodiment;

FIG. 11 is a cross-sectional side view illustrating the second embodiment;

FIG. 12 is a cross-sectional enlarged view illustrating the second embodiment;

FIG. 13 is a cross-sectional front view illustrating the second embodiment;

FIG. 14 is a perspective view illustrating the second embodiment of the connector device further includes an elastic pressing assembly;

FIG. 15 is an exploded perspective view of FIG. 14 illustrating a state that the elastic pressing assembly of the second embodiment is separated from a heat dissipating assembly; and

FIG. 16 is a cross-sectional side view of FIG. 14 illustrating a position relationship between the elastic pressing assembly and the heat dissipating assembly.

Reference numerals are presented as follows.
1, 1′ heat dissipating assembly
2, 2′ cold plate
21, 21′ body portion
211′ hollow cavity
212′ heat dissipating fin
213′ passageway
214′ cover plate
215′ inlet pipe end
216′ outlet pipe end
22, 22′ cantilever portion
221 U-shaped groove
3 cold pipe
31 main pipe portion
311 curved pipe segment
312 connecting pipe segment
32 inlet end
33 outlet end
4 receptacle assembly
41, 41′ inserting groove
411 groove opening
412, 412′ top opening
42, 42′ cage
421, 421′ bottom plate
422, 422′ side plate
423, 423′ rear plate
424, 424′ guiding surface
43 connector
5′ elastic pressing assembly
51′ fixing plate
52′ elastic member
7, 7′ board
8, 8′ pluggable assembly
9′ casing
X first direction
Y second direction

### DETAILED DESCRIPTION

Before the present disclosure is described in detail, it is noted that the similar elements are indicated by the same reference numerals in the following described content.

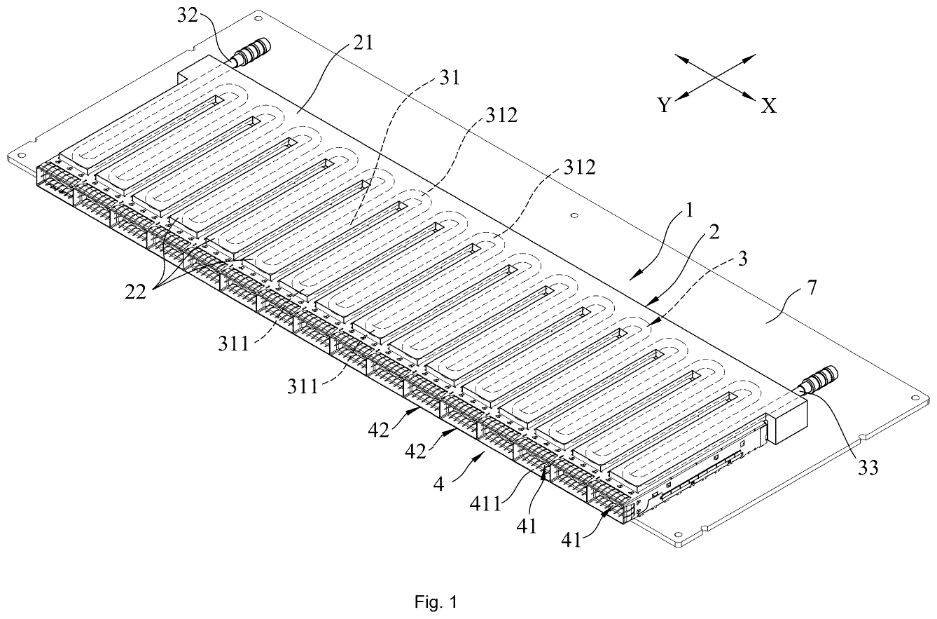

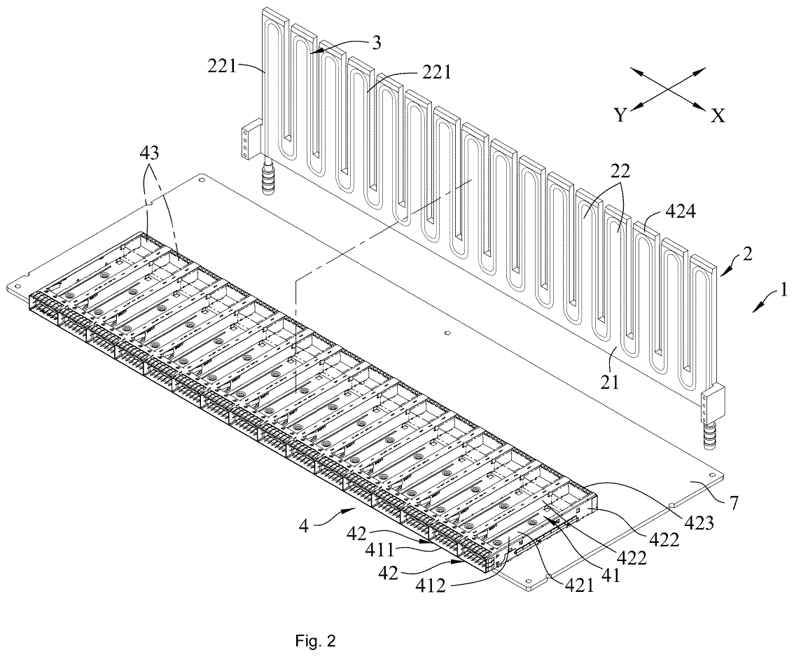

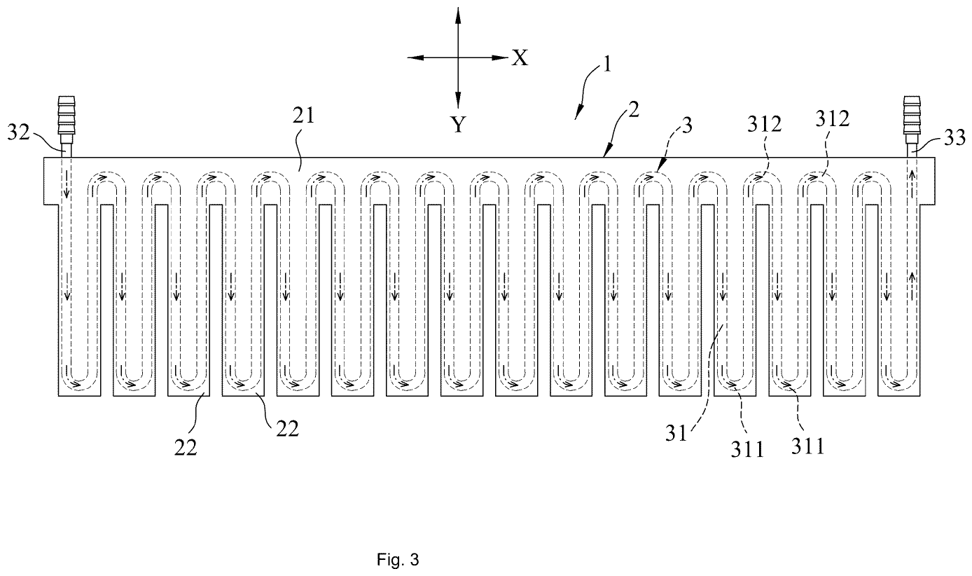

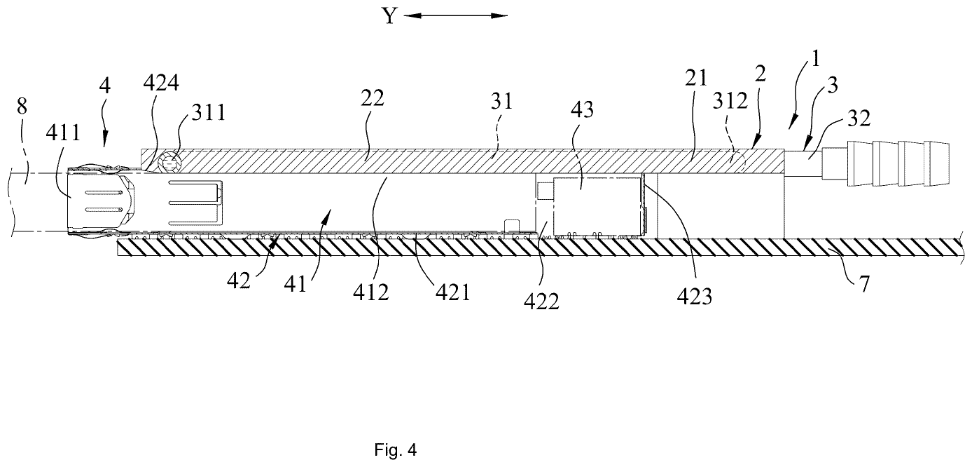

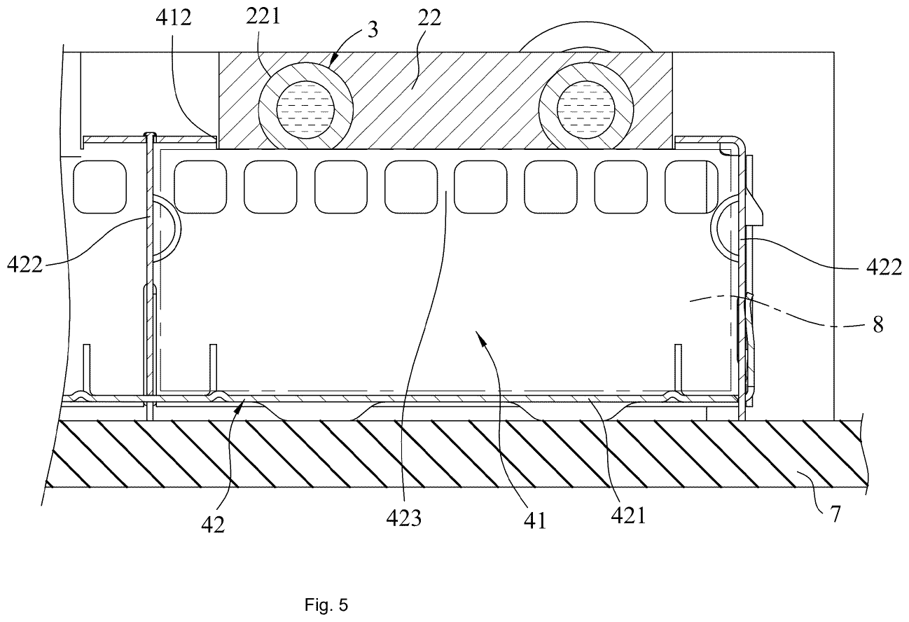

Referring to FIG. 1 to FIG. 5, a first embodiment of a connector device of the present disclosure is adapted to be provided on a board 7, and allows a plurality of pluggable assemblies 8 to mate therewith. In the first embodiment, the board 7 is for example but is not limited to a circuit board. Each pluggable assembly 8 is for example but is not limited to an optical fiber transmitting plug. The connector device includes a receptacle assembly 4 and a heat dissipating assembly 1.

The receptacle assembly 4 may be for example but is not limited to an optical module receptacle connector, and is used to allow the plurality of pluggable assemblies 8 removably mate therewith. The receptacle assembly 4 includes a plurality of cages 42 which are mounted on the board 7, are arranged along a first direction X and are spaced apart from each other, and a plurality of connectors 43 which are respectively provided in the plurality of cages 42. Each cage 42 defines an inserting groove 41. The inserting groove 41 extends along a second direction Y transversal to the first direction X, and includes a groove opening 411 which may allow each pluggable assembly 8 to enter therein and exit therefrom, and a top opening 412 which is formed to a top side of the inserting groove 41. In structure, each cage 42 has a bottom plate 421, two side plates 422 which extend upwardly from a left side and a right side of the bottom plate 421 respectively, and a rear plate 423 which extends upwardly from a rear side of the bottom plate 421. A height of a top edge of each side plate 422 is equal to a height of the top opening 412 and is higher than a height of a top edge of the rear plate 423. In the first embodiment, the first direction X is a left-right direction, the second direction Y is a front-rear direction, but in implementing applications, the arrangement directions also may be changed, and is not limited to those in the first embodiment.

In the first embodiment, the heat dissipating assembly 1 is provided to the board 7, and the heat dissipating assembly 1 includes a cold plate 2. The cold plate 2 is substantially in form of transversal L-shaped structure in a side view, and is designed as cantilever beam that one end thereof is fixed and the other end thereof is free. The cold plate 2 includes a body portion 21 which extends along the first direction X and is mounted on the board 7, a plurality of cantilever portions 22 which protrude from a side of a side of the body portion 21 toward the second direction Y, are suspended and are spaced apart from the board 7, and are respectively used to correspond to the plurality of cages 42, and a cold pipe 3 which extends in the plurality of cantilever portions 22. The plurality of cantilever portions 22 and the board 7 allow the receptacle assembly 4 to be provided therebetween. A bottom surface of each cantilever portion 22 forms a U-shaped groove 221. A bottom of each cantilever portion 22 protrudes and extends into the inserting groove 41 via the top opening 412 of each cage 42, and a rear end of the bottom of the cantilever portion 22 correspondingly rests above the rear plate 423 to be supported by the rear plate 423, a front end of the bottom of the cantilever portion 22 has a guiding surface 424. Moreover, in the first embodiment, the cold plate 2 includes sixteen cantilever portions 22, but in other implementing manners, the number of the cantilever portions 22 may increase or decrease as the number of the inserting grooves 41 which is included by the receptacle assembly 4. In the first embodiment, the body portion 21 and the plurality of cantilever portions 22 are integrally formed.

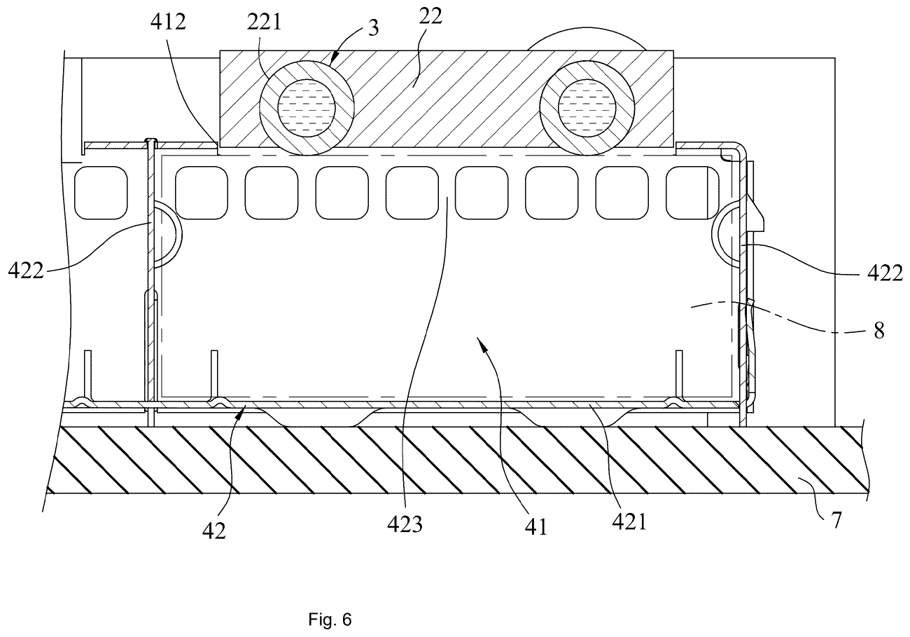

The cold pipe 3 is secured to the U-shaped grooves 221, and the cold pipe 3 includes an inlet end 32 and an outlet end 33 which are positioned to two opposite ends of the cold pipe 3 and respectively enter into and exit from the body portion 21, and a main pipe portion 31 which connects the inlet end 32 and the outlet end 33 and serpentinely extends in the plurality of cantilever portions 22 and the body portion 21. The main pipe portion 31 includes a plurality of curved pipe segments 311 which are respectively provided in the plurality of cantilever portions 22, and a plurality of connecting pipe segments 312 which are provided in the body portion 21 and each connect the two adjacent curved pipe segments 311. Each curved pipe segment 311 is in form of U-shape and an opening of the U-shape is rearwardly toward the body portion 21, each connecting pipe segment 312 is in form of reversed U-shape and an opening of the reversed U-shape is forwardly toward the plurality of cantilever portions 22. Certainly, the shape and the construction of the cold pipe 3 also may be changed and is not limited to those in the first embodiment. The cold pipe 3 may allow a cooling liquid (not shown) to flow therethrough, in the first embodiment, the cold pipe 3 is a copper pipe, but a material of the cold pipe 3 is not limited thereto, also may be other thermal conductive pipe materials which are used to allow the cooling liquid to flow therethrough. In the first embodiment, a bottom surface of the cold pipe 3 is in form of flatten shape to be flush with the bottom of the cantilever portion 22. But the design of the cold pipe 3 is not limited thereto, as shown in FIG. 6, in another implementing manner of the first embodiment, the bottom surface of the cold pipe 3 is in form of circular-arc shape and protrudes from the bottom of the cantilever portion 22.

When each pluggable assembly 8 inserts into the inserting groove 41, the pluggable assembly 8 contacts the guiding surface 424 of the cantilever portion 22, the cantilever portion 22 is pushed upwardly and presses against a top of the pluggable assembly 8, and the cold pipe 3 is allowed to directly contact a top surface of the pluggable assembly 8, so in the first embodiment, heat generated by the pluggable assembly 8 may be conducted to the cooling liquid in the main pipe portion 31 via the main pipe portion 31, and perform heat exchange with the cooling liquid, a temperature of the pluggable assembly 8 is lowered and heat is dissipated out, heat dissipating effect is better. Because the main pipe portion 31 is secured to the cantilever portion 22, even if the cantilever portion 22 generates crack due to deformation, because the cooling liquid only flows in the cold pipe 3, it may avoid leakage problem of the cooling liquid occurring.

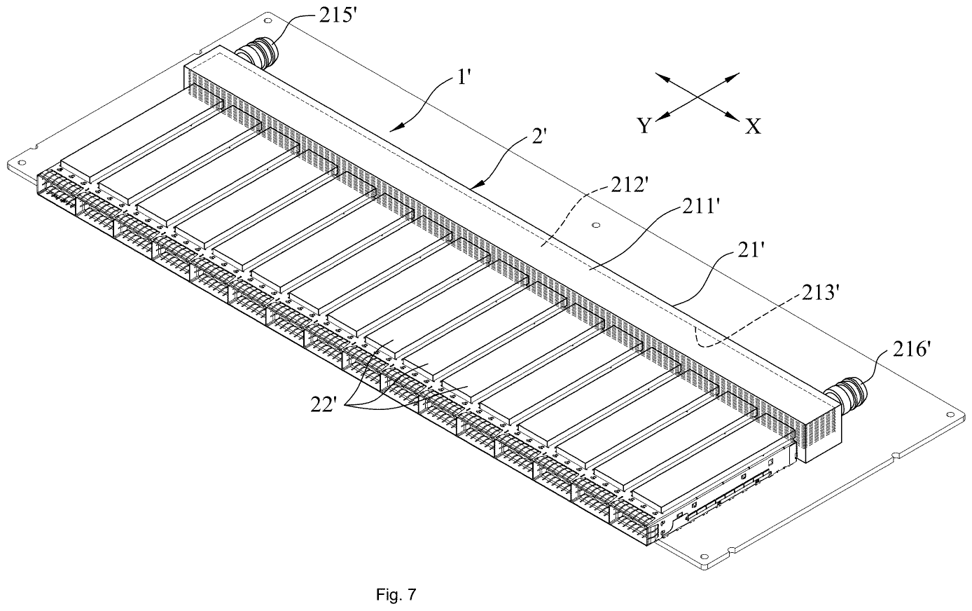

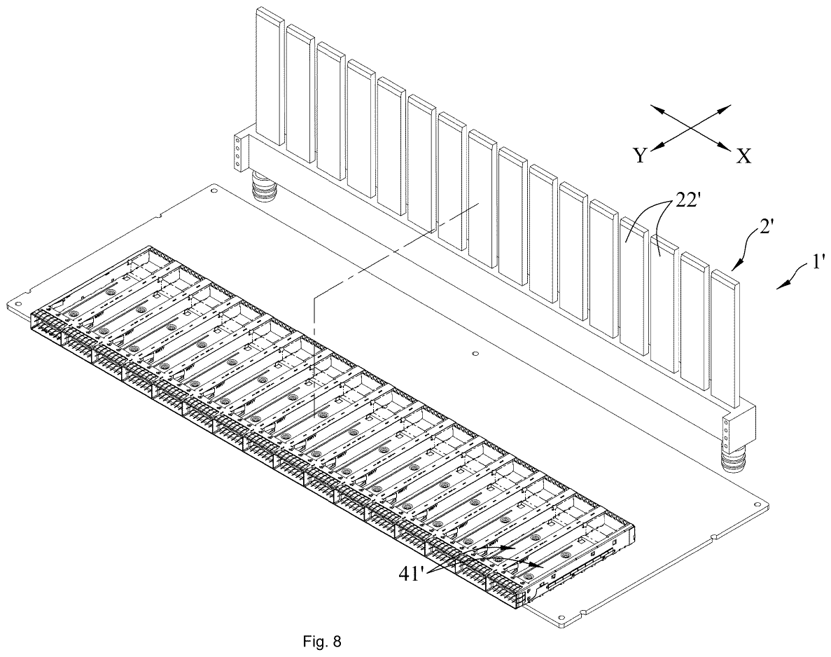

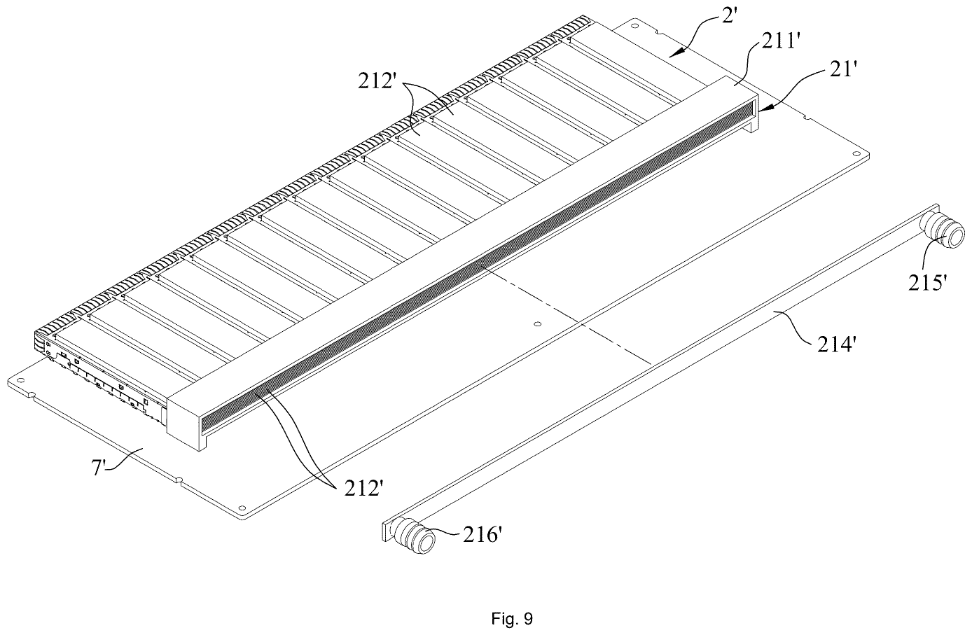

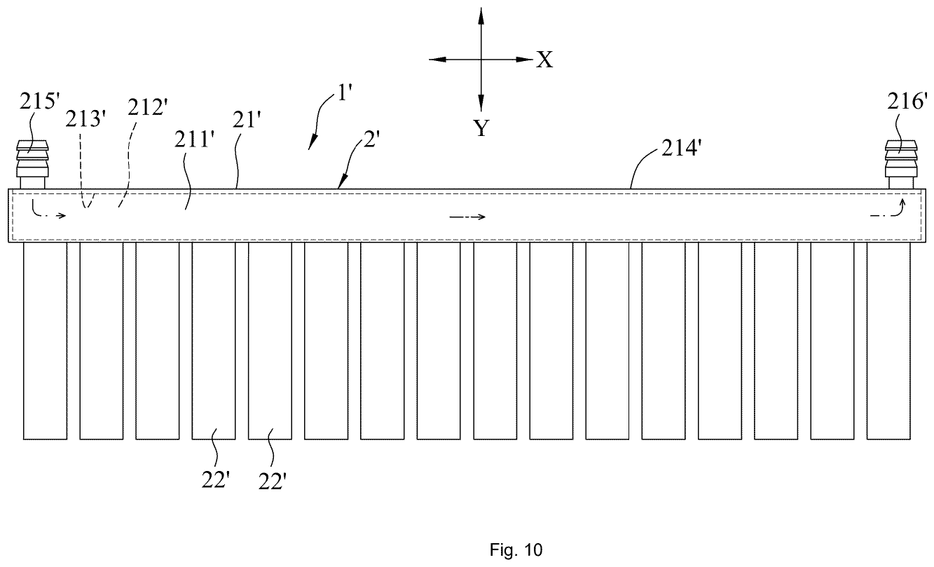

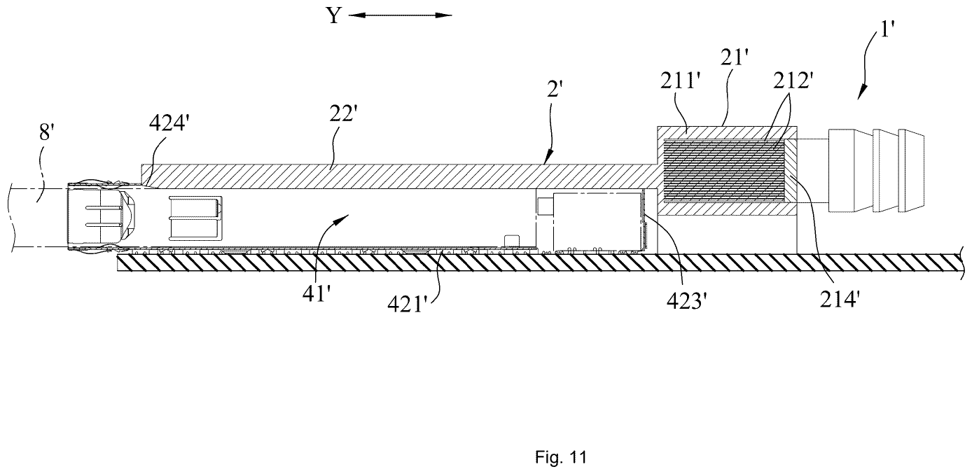

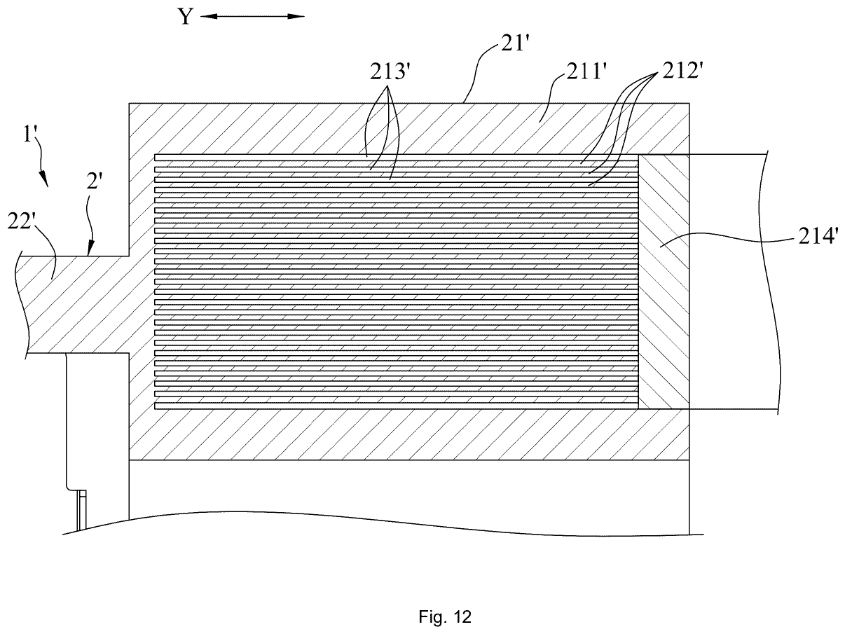

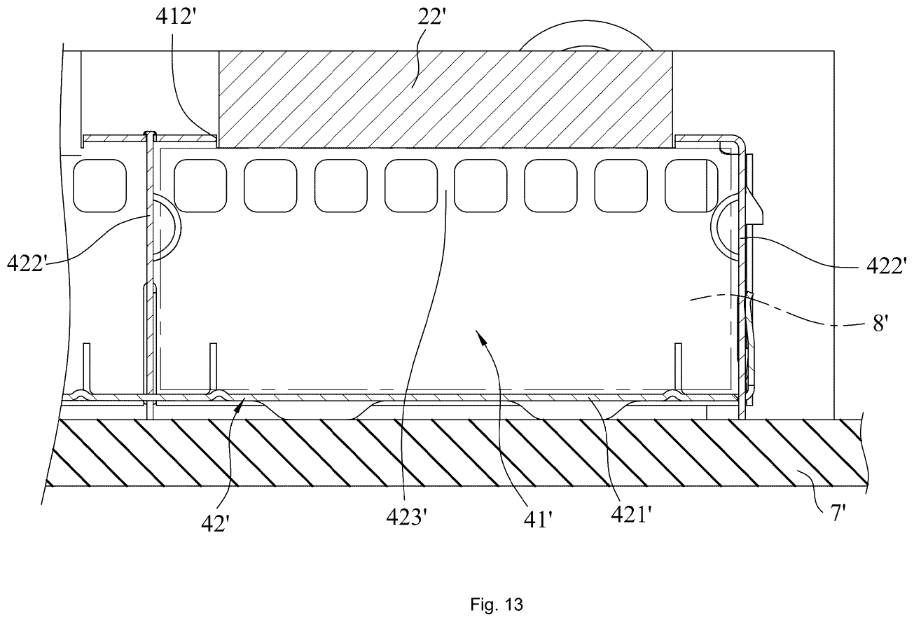

Referring to FIG. 7 to FIG. 13, a construction of a second embodiment of the connector device of the present disclosure is substantially the same as that of the first embodiment, difference between the two embodiments lies in that: the cold pipe (see reference numeral 3 in FIG. 1) is omitted in the heat dissipating assembly 1′ of the second embodiment, and a layout design of the cold plate 2′ is changed. The cold plate 2′ only makes the body portion 21′, which fixedly mounted on the board 7′, form a plurality of passageways 213′ which allow the cooling liquid flow therethrough, the plurality of cantilever portions 22′ become solid heat dissipating plates. In the second embodiment, the body portion 21′ and the plurality of cantilever portions 22′ may be integrally formed.

Further, with respect to a design of the body portion 21′, the body portion 21′ includes a hollow cavity 211′ which extends along the first direction X and is in form of rectangular box, a plurality of heat dissipating fins 212′ which extend along the first direction X, are arranged up and down in the hollow cavity 211′ and are spaced apart from each other, a cover plate 214′ which covers a rear side of the hollow cavity 211′, and an inlet pipe end 215′ and an outlet pipe end 216′ which are provided to two ends of the cover plate 214′ respectively and protrude rearwardly. The plurality of heat dissipating fins 212′ and the hollow cavity 211′ together define the plurality of passageways 213′, and the plurality of passageways 213′ are communicated with the inlet pipe end 215′ and the outlet pipe end 216′. In the second embodiment, each heat dissipating fin 212′ is a horizontal sheet, and at least one side of each heat dissipating fin 212′ is integrally connected to the hollow cavity 211′. Certainly, in implementing, the extending direction and the arrangement manner of the plurality of heat dissipating fins 212′ also may be changed, for example, the plurality of heat dissipating fins 212′ are arranged front and rear in the hollow cavity 211′ and are spaced apart from each other, and each heat dissipating fin 212′ is a vertical sheet, thus the design is not limited to the second embodiment.

The plurality of cantilever portions 22′ are correspondingly positioned above the plurality of cages 42′ respectively. Each cage 42′ has the bottom plate 421′, the two side plates 422′ and the rear plate 423′ which define the inserting groove 41′. A bottom of each cantilever portion 22′ protrudes and extends into the inserting groove 41′ via the top opening 412′ of each cage 42′, and a rear end of the bottom of the cantilever portion 22′ correspondingly rests above the rear plate 423′ to be supported by the rear plate 423′. A front end of the bottom of the cantilever portion 22′ has the guiding surface 424′. In use, the bottom of the cantilever portion 22′ contacts a top surface of the pluggable assembly 8′, heat generated by the pluggable assembly 8′ may be directly conducted rearwardly from the cantilever portions 22′ to the body portion 21′, and then be dissipated out by means of the cooling liquid, heat dissipating effect is good.

Because the plurality of cantilever portions 22′ of the second embodiment are solid constructions which are not provided with any passageway, leakage of the cooling liquid due to flex deformation of the plurality of cantilever portions 22′ does not occur completely. Moreover, by provision of the plurality of heat dissipating fins 212′, a contact area with the cooling liquid can be further increased, so heat dissipating effect may be promoted.

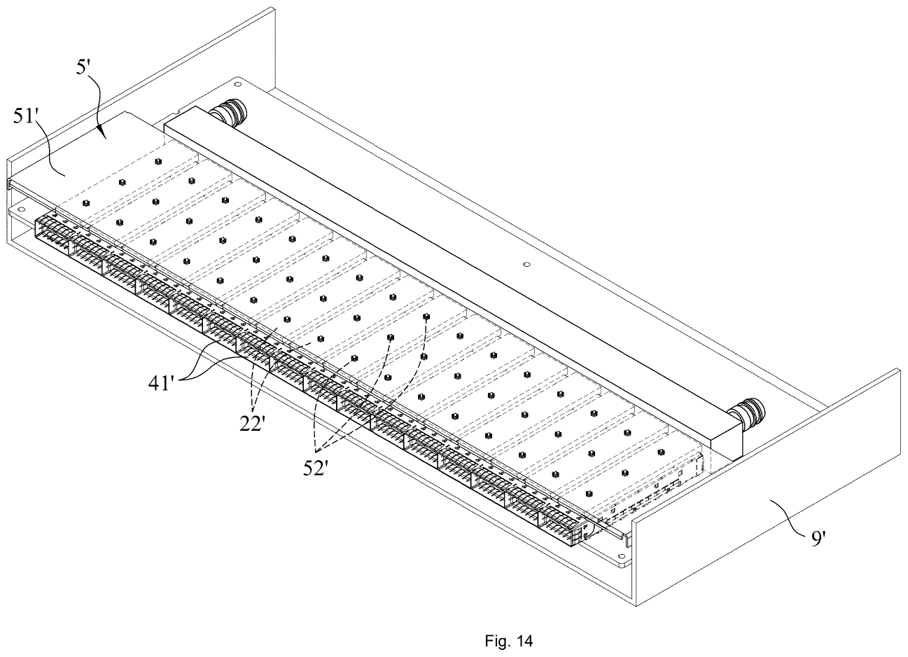

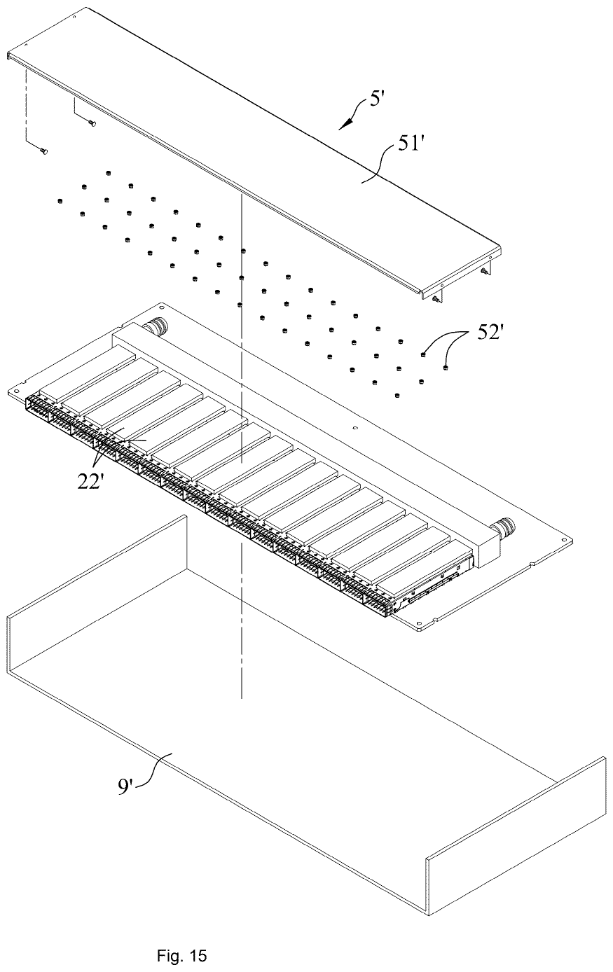

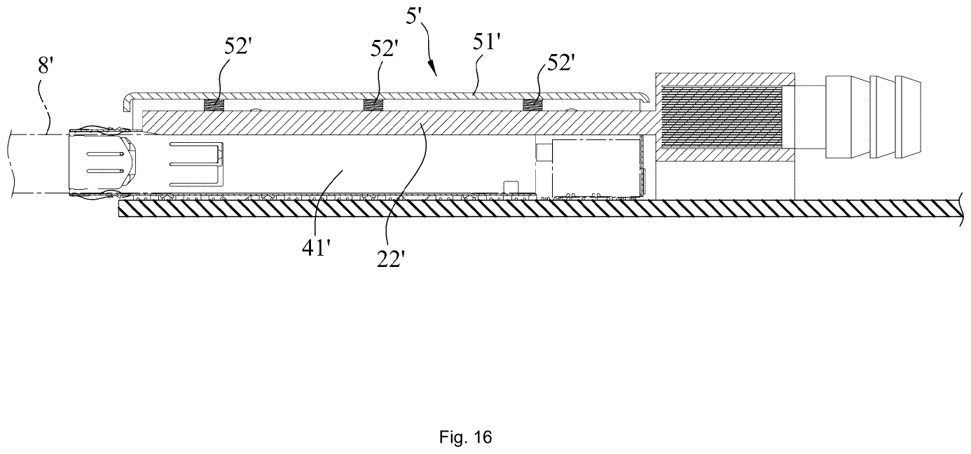

Referring to FIG. 14, FIG. 15 and FIG. 16, in addition, taking the second embodiment as example, the connector device of the present disclosure may further include an elastic pressing assembly 5′ which is mounted above the plurality of cantilever portions 22′. The elastic pressing assembly 5′ includes a fixing plate 51′ which is positioned above and spaced apart from the plurality of cantilever portions 22′, and a plurality of elastic members 52′ which are provided between the plurality of cantilever portions 22′ and the fixing plate 51′. In the second embodiment, two sides of the fixing plate 51′ is fixedly mounted on a casing 9′, but implementation is not limited thereto, the fixing plate 51′ also may be mounted to other position. The plurality of elastic members 52′ are for example but are not limited to compressible springs, and have elastic forces which drive the plurality of cantilever portions 22′ to elastically press downwardly toward the plurality of inserting groove 41′ respectively. Therefore, if the connector device is subjected to dimensional space constraint or special requirement in design to result in that the plurality of cantilever portions 22′ cannot provide the desirable downward pressure, the elastic pressing assembly 5′ may be added to provide the desirable downward pressure. Certainly, the construction of the elastic pressing assembly 5′ is also adapted to be provided to the first embodiment, the description thereof is not repeated herein.

In conclusion, in the connector device of the present disclosure, a design that the cold pipe 3 is provided in the cantilever portions 22 and the cold pipe 3 directly contacts the top surface of the pluggable assembly 8 may have a technical effect that thermal conductivity is better and leakage of the cooling liquid is prevented, so the object of the present disclosure is indeed attained.

On the other hand, in the connector device of the present disclosure, that the cantilever portions 22′ of the cold plate 2′ employ solid heat dissipating plates may promote heat dissipating effect, moreover, the cooling liquid only flows in the passageways 213′ of the body portion 21′, does not flow to the plurality of cantilever portions 22′ which are connected with the body portion 21′, a technical effect that leakage of the cooling liquid does not occur due to flex deformation of the plurality of cantilever portions 22′ is achieved, so the object of the present disclosure is indeed attained.

However, the above description is only for the embodiments of the present disclosure, and it is not intended to limit the implementing scope of the present disclosure, and the simple equivalent changes and modifications made according to the claims and the contents of the specification are still included in the scope of the present disclosure.

What is claimed is:

1. A connector device, being provided to a board and allowing a pluggable assembly to mate therewith, the connector device comprising:
a receptacle assembly comprising a plurality of cages and a plurality of connectors respectively provided in the plurality of cages, each cage being provided with a top opening; and
a heat dissipating assembly comprising a cold plate, the cold plate comprising a body portion, a plurality of cantilever portions which protrude from the body portion and are spaced apart from the board, and a cold pipe which extends in the plurality of cantilever portions, the body portion and the plurality of cantilever portions being integrally formed, the receptacle assembly being positioned between the board and the plurality of cantilever portions, bottoms of the plurality of cantilever portions respectively extending into the top openings of the plurality of cages, when the pluggable assembly inserts into the receptacle assembly, the cold pipe contacting a top surface of the pluggable assembly.

2. The connector device of claim 1, wherein
each cantilever portion forms a U-shaped groove, the cold pipe is secured to the U-shaped groove, and the cold pipe extends out of the bottom of the cantilever portion, or is flush with the bottom of the cantilever portion.

3. The connector device of claim 1, wherein
each cage has a bottom plate, two side plates which respectively extend upwardly from a left side and a right side of the bottom plate, and a rear plate which extends upwardly from a rear side of the bottom plate,
a height of a top edge of each side plate is equal to a height of the top opening and is higher than a height of a top edge of the rear plate, the rear plate is used to support the corresponding cantilever portion.

4. The connector device of claim 1, wherein
the cold pipe comprises an inlet end, an outlet end and a main pipe portion which connects the inlet end and the outlet end,
the main pipe portion extends in the plurality of cantilever portions.

5. The connector device of claim 1, wherein
the cold pipe is a copper pipe.

6. The connector device of claim 4, wherein
the main pipe portion comprises a plurality of curved pipe segments which are respectively provided in the plurality of cantilever portions, and a plurality of connecting pipe segments which are provided in the body portion and each connect the two adjacent curved pipe segments,
each curved pipe segment is in form of U-shape and an opening of the U-shape is toward the body portion,
each connecting pipe segment is in form of reversed U-shape and an opening of the reversed U-shape is toward the plurality of cantilever portions.

7. The connector device of any one of claims 1, further comprising:
an elastic pressing assembly,
the elastic pressing assembly comprising a fixing plate which is positioned above and spaced apart from the plurality of cantilever portions, and a plurality of elastic members which are provided between the plurality of cantilever portions and the fixing plate,
the plurality of elastic members respectively applying elastic forces toward the plurality of cantilever portions.

8. A connector device, being provided to a board and allowing a pluggable assembly to mate therewith, the connector device comprising:
a receptacle assembly comprising a plurality of cages and a plurality of connectors respectively provided in the plurality of cages, each cage being provided with a top opening; and
a heat dissipating assembly comprising a cold plate, the cold plate comprising a body portion, and a plurality of cantilever portions which protrude from the body portion and are spaced apart from the board, the receptacle assembly being positioned between the board and the plurality of cantilever portions, bottoms of the plurality of cantilever portions respectively extending into the top openings of the plurality of cages, the body portion comprising a hollow cavity and a plurality of heat dissipating fins which are arranged in the hollow cavity, the plurality of heat dissipating fins and the hollow cavity forming a plurality of passageways which allow a cooling liquid to flow therethrough, the plurality of cantilever portions being solid heat dissipating plates, and being thermally engaged with the body portion respectively, when the pluggable assembly inserts into the receptacle assembly, the bottom of the cantilever portion contacting a top surface of the pluggable assembly.

9. The connector device of claim 8, wherein
each cage has a bottom plate, two side plates which respectively extend upwardly from a left side and a right side of the bottom plate, and a rear plate which extends upwardly from a rear side of the bottom plate,
a height of a top edge of each side plate is equal to a height of the top opening and is higher than a height of a top edge of the rear plate, the rear plate is used to support the corresponding cantilever portion.

10. The connector device of any one of claims 8, further comprising:
an elastic pressing assembly,
the elastic pressing assembly comprising a fixing plate which is positioned above and spaced apart from the plurality of cantilever portions, and a plurality of elastic members which are provided between the plurality of cantilever portions and the fixing plate,
the plurality of elastic members respectively applying elastic forces toward the plurality of cantilever portions.
